(19) United States
(12) Patent Application Publication
(10) Pub. No.: US 2022/0392506 A1
(43) Pub. Date: Dec. 8, 2022

(54) METHOD FOR CONTROLLING FUNCTION ELEMENTS AND DEVICE FOR USE IN BIOPROCESS ENGINEERING AND/OR MEDICAL TECHNOLOGY

(71) Applicant: EPPENDORF SE, Hamburg (DE)

(72) Inventors: Wolfgang Streule, Titz-Rödingen (DE); Guido Ertel, Dormagen (DE)

(73) Assignee: EPPENDORF SE, Hamburg (DE)

(21) Appl. No.: 17/786,270

(22) PCT Filed: Dec. 10, 2020
(86) PCT No.: PCT/EP2020/085618

§ 371 Date: Jun. 16, 2022

(30) Foreign Application Priority Data
Dec. 18, 2019 (EP) 19217653.5

(51) Int. Cl. G11C 11/16; G06F 12/02

(52) U.S. Cl. CPC G11C 11/161; G06F 12/0238; G06F 12/0246

(57) ABSTRACT

A method for controlling functional elements and a device for use in bioprocess engineering or medical technology is disclosed. The method includes providing a first functional element, which has a memory, in which items of element information having specifications about the type and the function of the functional element are stored, and providing a second functional element. The method includes connecting the first and the second functional element to a control unit, reading the items of element information out of the first functional element and carrying out a check of the read-out items of element information from the second functional element or using items of information which are stored in the control unit. The first functional element is controlled by the control unit in dependence on the check or in dependence on the items of element information.

### CROSS-REFERENCE TO FOREIGN PRIORITY APPLICATION

The present application claims the benefit under 35 U.S.C. § 119(b), 119(e), 120, 121, 365(c), and/or 386(c) of PCT/EP2020/085618 filed Dec. 10, 2020, which claims priority to European Patent Application No. 19217653.5 filed Dec. 18, 2019.

### FIELD OF THE INVENTION

The invention relates to a method for controlling functional elements in bioprocess engineering and/or medical technology, and to a device for use in bioprocess engineering and/or medical technology.

### BACKGROUND OF THE INVENTION

Various functional elements are often used in complex processes in bioprocess engineering and medical technology. The process reliability is of particular importance, in particular, in these areas of application, in particular, the safety of the users and/or patients, the reproducibility of the process, and/or the process result as a whole. Processes in bioprocess engineering and/or medical technology usually take place in monitored environments, wherein, in particular, guidelines for quality control of the process sequences and the process environment are also to be maintained, which is also referred to as Good Manufacturing Practice (GMP).

The demands of GMP, in particular, on complex processes and process environments are high and represent a not insignificant expenditure in practice.

### SUMMARY OF THE INVENTION

It is therefore an object of the present invention to provide an improved method for controlling functional elements and an improved device for use in bioprocess engineering and/or medical technology. Furthermore, it is an object of the present invention to provide a method for controlling functional elements and a device for use in bioprocess engineering and/or medical technology, which increase the process reliability and/or facilitate maintaining quality guidelines such as GMP and preferably provide efficient and/or cost-effective solutions for this purpose.

This object is achieved according to the invention by a method for controlling functional elements in bioprocess engineering and/or medical technology, comprising providing a first functional element, which has a memory in which items of element information are stored and the items of element information comprise specifications about the type and the function of the first functional element, providing a second functional element, connecting the first and the second functional element to a control unit, reading the items of element information out of the first functional element, carrying out a check of the read-out items of element information of the first functional element using items of element information which are read out from the second functional element and/or using items of information which are stored in the control unit, controlling at least one of the first and the second functional element in dependence on the check and/or in dependence on the items of element information, and storing items of process information in the memory of the first functional element.

In the method described here, a first and a second functional element and a control unit are provided and the functional elements are connected to this control unit. The functional elements can be connected in a wired or wireless manner. The first functional element has a memory in which items of element information on this first functional element are stored.

As is described in more detail hereinafter, the second functional element can also have a memory in which items of element information on the second functional element are stored. The items of element information of the respective functional element contain specifications about the type and the function of the respective functional element.

The items of element information are read out from the first functional element by the control unit. The readout can also take place in a wired or wireless manner.

According to the method described here, a check of the read-out items of element information of the first functional element using items of element information which are read out from the second functional element and/or using items of information which are stored in the control unit is carried out, for example, in the control unit or in an evaluation unit, which is preferably connected to the control unit in a wired or wireless manner. In particular, the specifications about the type and function of the first functional element can thus be compared in this case to the type and function of the second functional element or to other specifications, which are required or helpful for successfully carrying out a process. These items of information can be items of element information read out from the second functional element and/or can be items of information which are stored in the control unit.

A result of the check can be, for example, that specific functional elements are not compatible with one another or are only compatible with one another under specific conditions. A further example of a result of a check is that a functional element is not usable for a planned process. In such cases, these noncompatible or non-usable functional elements would preferably also not be controlled. In such cases, for example, a warning message can be generated and output which indicates the lack of compatibility or usability. A further example of a result of the check is that certain functional elements or the combinations thereof are only compatible with one another under specific conditions and/or are only usable in specific port process variants. Such a result of the check can then preferably be taken into consideration during the control of the respective functional elements, so that it is ensured that the respective functional element only operates in the compatible range, for example, a specific temperature range.

The first functional element and/or the second functional element is then controlled in dependence on this check and/or in dependence on the items of element information. For example, in the control of the first functional element, both the items of element information of the first functional element and also results and/or findings obtained during the check can be taken into consideration. If items of element information are present for the second functional element, for example, because they were read out from the second functional element or because these items of element information of the second functional element are stored as information in the control unit, the second functional element can also be controlled in dependence on the items of element information of the second functional element. Additionally or alternatively, the second functional element can be controlled in dependence on the check and the results and/or findings generated in this case.

The method described here furthermore provides that items of process information are stored in the memory of the first functional element. If the second functional element also has a memory, it is preferred that items of process information can also be stored in the memory of the second functional element.

The described process steps do not necessarily have to be carried out in the described sequence, but can also—if reasonable and feasible—be carried out in another sequence. In particular, the steps of carrying out a check, controlling the first and/or second functional element, and/or storing items of process information can take place in a different sequence and/or in arbitrary repetition.

As is also described in more detail hereinafter, in addition to the first and second functional element, further functional elements can also be used in the method described here and/or can be part of the device described here. The properties described for the first and/or second functional element preferably apply in this case. Details and/or advantages are also applicable to one, multiple, or all of the further functional elements. Furthermore, it is preferably provided that one, multiple, or all of the further functional elements are connected to the control unit and/or to the evaluation unit, preferably in a wired or wireless manner. One, multiple, or all of the functional elements can also be connected to one another, preferably in a wired or wireless manner.

When reference is made hereinafter to one functional element, these specifications preferably also apply to one, multiple, or all further functional elements. In addition, specifications which are made in the plural hereinafter with reference to functional elements are also applicable to a single functional element, for example, the first and/or the second functional element.

An optional evaluation unit can preferably be connected in a wired or wireless manner to the control unit and/or can be arranged spatially spaced apart from the control unit or can also be formed integrally with the control unit.

The method described here has various advantages. Because the first functional element has a memory having items of element information which can be read out by the control unit, it is no longer necessary to manually acquire these items of element information. Rather, it is possible that a simplified, preferably also automated readout process and/or information exchange takes place.

A further advantage results in that the items of element information read out from the first functional element can be checked using further items of information, namely using items of element information which are read out from the second functional element, and/or using items of information which are stored in the control unit. As is also described in more detail hereinafter, for example, compatibilities and/or other checks relevant for the process reliability can be carried out for this purpose, so that the control of the first and/or second functional element can then take place in dependence on the results and/or findings of this check and/or in dependence on the respective items of element information. It can thus be ensured in this way that, for example, functional elements which are only compatible with one another in specific ranges are also only operated in this compatible range (for example, a specific temperature range). A further advantage of the method described here results in that items of information not only can be read out from the memory of the first functional element, but also items of information, namely items of process information, can be stored in the memory of the first functional element. The possibility results in this way of being able to store items of process information again and again in the memory of the functional element over the life cycle of the functional element. These items of process information can preferably also be read out by the control unit and furthermore can preferably be taken into consideration when carrying out the check. In this way, for example, functional elements, the maximum operating runtime of which has been reached, can be excluded from a use.

The first and/or the second functional element is preferably selected from a group comprising sensor, and/or actuator, and/or apparatus component.

The first and/or the second functional element can thus be designed, for example, as a sensor, actuator, or apparatus component. A functional element designed as a sensor can be, for example, a temperature sensor, a pH sensor, or a level sensor. A functional element designed as an actuator can be, for example, a stirrer for a bioreactor, a stirring drive, a temperature control unit (for example, a heating sleeve, a cooling element, or a heating element), or a gassing element. A functional element designed as an apparatus component can be, for example, a vessel, such as a bioreactor vessel, a head plate, in particular a head plate for a bioreactor, or a hose, for example, an exhaust hose or a gassing hose.

As also already described above, it is preferred that the second functional element also has a memory, in which items of element information are stored, and the items of element information comprise specifications about the type and the function of the second functional element.

In one preferred refinement, the method comprises providing one or more further functional elements, wherein preferably one or more or all of the further functional elements each has a memory in which items of element information are stored and the items of element information comprise specifications about the type and the function of the respective functional element. If further functional elements are provided, it is furthermore preferred that one, multiple, or all of these further functional elements each have a memory in which the items of element information on the respective functional element are stored.

Furthermore, it is preferably provided that the method comprises reading the items of element information out of the second functional element, and/or reading the items of element information out of one, multiple, or all of the further functional elements.

It is then also preferred in particular here that when carrying out the check, the read-out items of element information of the second and/or one, multiple, or all further functional elements are taken into consideration.

The preferred embodiments described here each have various advantages individually, but also in their respective possible combinations. Complex processes in bioprocess engineering and/or medical technology often require a large number of functional elements. The more of these functional elements which have a memory having the respective items of element information, which can then preferably also be read out by the control unit and can possibly also be taken into consideration when carrying out the check, the more strongly, for example, the process reliability and maintaining quality guidelines such as GMP can also be assisted and/or simplified in complex processes.

According to one preferred embodiment, the specifications about the type of the functional element comprise whether the respective functional element is designed as a sensor, actuator, or apparatus component.

Furthermore, it is preferred that the specifications about the type of the functional element comprise a serial number of the respective functional element and/or an article number of the respective functional element and/or comprise a type specification of the respective functional element and/or comprise specifications about the production of the respective functional element.

A type specification of a functional element can further specify the specific type of the functional element. For example, with a stirring drive, it can be specified as a type specification that it is an overhead drive and/or a magnetic drive. With an apparatus component designed as a hose, for example, the type specification can comprise that it is a heatable exhaust hose. A further preferred type specification for functional elements, for example, for bioreactor vessels and/or head plates and/or further apparatus components, is also the specification as to whether it is multiuse or single-use elements. A further preferred type specification of a functional element comprises the material and/or a material combination of the functional element, for example, whether a bioreactor vessel is made of glass or plastic.

Specifications about the manufacturing of the respective functional element can comprise, for example, the materials and/or manufacturing methods and/or tools used during the manufacturing. Furthermore, the location and/or time of the manufacturing and/or the performance of individual production steps can preferably be included. Furthermore, specifications about the shipping and/or the storage of the functional element can also preferably be included. These specifications about the manufacturing of the respective functional element also advantageously enable functional elements from specific batches or having a specific manufacturing history to be able to be identified quickly, for example, in the context of a recall.

In addition, it is in particular preferred that the specifications about the function of the functional element comprise specifications about operating parameters of the respective functional element and/or specifications about compatibilities of the respective functional element with other functional elements, and/or specifications about the usability of the respective functional element in various processes, and/or specifications about the calibration of the respective functional element, and/or specifications about the CE identification of the respective functional element, and/or specifications about the service intervals to be observed and/or the maximum operating duration of the respective functional element.

Specifications about the operating parameters of a respective functional element can be, for example, maximum values, limiting values, permissible parameters, and/or permissible operating modes. For a stirring drive, for example, a permissible speed range, in particular minimum and maximum speeds, specifications about permissible current, permissible voltage, or the like can be stored. Permissible temperature ranges, in particular minimum or maximum temperatures, for example, are preferred operating parameters in a large number of functional elements.

The specifications about compatibilities of the respective functional element with other functional elements can include, for example, items of information about whether a specific temperature control unit is only to be used with glass vessels and/or may only be operated up to a specific maximum temperature upon use with plastic or single-use vessels, for example.

Specifications about the usability of the respective functional element in various processes can include, for example, items of information about whether specific types of stirrers may only be used for specific biotechnological processes and not for others. This can be advantageous, for example, if sensitive cell cultures are to be thoroughly mixed, and only stirrers having correspondingly shaped stirring elements are to be used for this purpose.

The specifications about the calibration of the respective functional element can include, for example, specifications about which calibration was carried out in the respective functional element and/or specifications about which points in time and/or at which intervals which calibration of the respective functional element are to be carried out how. This can advantageously also permit an automatic calibration of the respective functional element.

The specifications about the CE identification of the respective functional element are also advantageous to ensure the process reliability.

The specifications about the service intervals to be observed and/or a maximum operating duration of the respective functional element also promote the process reliability, since warning messages are preferably output when functional elements are to be used, the service intervals and/or maximum operating duration of which has been exceeded. A maximum operating duration can preferably include specifications about a maximum total operating duration in the meaning of a maximum product lifecycle and/or about how long a functional element may be used and/or operated at most consecutively in a specific process.

As is also described in more detail hereinafter, some or all of the specifications about the type and/or the function of the functional element can be changed and/or supplemented. It is advantageous here if specific specifications are change-protected and/or write-protected, so that these specifications cannot be changed during the entire life cycle of the functional element. Other specifications in turn can preferably be supplemented and/or changed, for example, to note maintenance measures which have been carried out and/or, for example, to note a maximum operating duration shortened for specific reasons and/or to add new findings with respect to compatibilities, for example, with newly developed functional elements.

Specifications which can be changed and/or supplemented can preferably be subject to different authorizations, so that specific specifications can only be carried out by specific authorities authorized for this purpose.

In a further preferred embodiment, it is provided that items of information which are stored in the control unit comprise specifications about compatibilities of functional elements, and/or specifications about the usability of functional elements in various processes, and/or specifications about processes to be carried out, such as the type and/or duration of the respective process, and/or specifications of the process parameters to be used in a process.

The specifications already described above about compatibilities of functional elements can also be stored in the control unit. This has the advantage, for example, that a large number of specifications about compatibilities of various functional elements, for example, also those which have been newly added, can be stored with an update of the control unit simultaneously.

The specifications which are required for carrying out processes are preferably also stored in the control unit, in particular, the type and/or duration of the process to be carried out and/or the process parameters to be used in a process. Together with the specifications about the type and function of the functional elements, the items of information stored in the control unit can advantageously be used when carrying out the check, for example, to establish whether the process parameters to be used in a process to be carried out and/or the functional elements to be used in the process are permissible and suitable for this purpose.

In a further preferred embodiment, the items of process information comprise specifications about a process which has been carried out, such as type and/or duration of the process, and/or specifications of the process parameters used in a process, and/or specifications of the operating parameters, using which the respective functional element and/or further functional elements were operated in a process, and/or specifications about further functional elements used together with the respective functional element, in particular, the items of element information thereof or parts thereof, and/or specifications about process results and/or process errors.

Items of process information which can be stored in the functional element preferably include items of information which can provide information about when, where (for example, in which process), and how (for example, with which other functional components and/or with which operating and/or process parameters) a functional element was used. These specifications can be used, for example, to establish or change service intervals and/or required maintenance measures and/or a maximum operating duration.

In a further embodiment, it is preferred that carrying out the check comprises comparing the compatibilities of functional elements, in particular, with respect to the joint use thereof and/or the usability thereof in a planned process and/or the usability thereof in a planned process environment.

When carrying out the check, it is preferred, in particular, that the compatibilities of functional elements with one another and/or in specific processes and/or in specific process environments are checked. For this purpose, the items of information present for this purpose are preferably compared, for example, in the control unit and/or an evaluation unit, and furthermore preferably a comparison result is evaluated.

Examples of checks can be that it is checked whether for a process to be carried out and the process parameters provided for this purpose and the process environment provided for this purpose it is checked whether the functional elements provided for the use in this process are suitable, in particular, with respect to the specifications about the type and function of these functional elements. For example, for the cultivation of a cell culture in a single-use bioreactor, it would preferably be able to be checked, among other things, whether all functional elements are designed for the use with a single-use bioreactor, and whether the process to be carried out does not exceed a maximum temperature to be observed for a single-use bioreactor. Furthermore, it would be able to be checked, for example, whether the stirrer provided for use also has a design of the stirring elements which is suitable for the cultivation of cell cultures. Similar checks can be carried out for gassing, exhaust gas routing, supply or removal of media, temperature monitoring, pH monitoring, and other areas.

Carrying out a check in consideration of the respective items of information and/or specifications has the advantage, among other things, that the result of this check can be taken into consideration in the control of one or more functional elements. For example, a maximum speed for the stirring drive can be predetermined in a specific process, such as the cultivation of cell cultures. The drive would accordingly then be controlled by the control unit so that it does not exceed this maximum speed predetermined by the process, although the maximum permissible speed of the drive is possibly well above this. Furthermore, for example, a temperature control unit can be activated so that it does not exceed a specific temperature which is permissible at most for the process, for example, so as not to endanger the cell cultures, even if the temperature control unit has a significantly higher heating power.

A further preferred embodiment is distinguished by configuring the first and/or the second and/or one or more of the further functional elements and/or a process to be carried out in dependence on the check. The configuration can preferably take place after connection of the functional element or elements to the control unit, furthermore preferably after the readout of the items of element information, furthermore preferably after carrying out the check. The configuration can preferably take place before or in parallel to the control of the functional elements.

The configuration of functional elements and/or processes can preferably comprise the selection and/or setting of operating parameters and/or process parameters and/or setting options and the like. For example, functional elements can have different operating modes or setting options and/or processes to be carried out can be executed in different possible variants. If it is shown in dependence on the check that the constellation of the functional elements to be used and the process to be carried out require a specific type or variant of the process and/or specific settings and/or operating parameters of functional elements, these are preferably configured accordingly by the control unit.

A further preferred embodiment of the method is characterized by storing items of process information in the memory of the control unit, and/or storing items of process information in a memory of an evaluation unit.

Preferably, items of process information can be stored not only in the memory of one or more functional elements, but also in the memory of the control unit and/or in the memory of the evaluation unit. In this way, items of process information are also available at these points for further checks and/or evaluations. The items of information stored in the memory of the control unit and/or in the memory of the evaluation unit can be identical to the items of information stored in one or more of the functional elements or can differ therefrom.

A further preferred exemplary embodiment is characterized by storing items of service information in the memory of the first and/or the second and/or a further functional element, and/or storing items of customer information in the memory of the first and/or the second and/or a further functional element.

Items of service information can include, for example, specifications which are relevant for the maintenance and/or operational feasibility of functional elements. Preferably, only specific authorities are authorized to initiate the storage of items of service information in the memory of a functional element, for example, appropriately authorized service technicians. Items of customer information can comprise, for example, items of user-specific information, for example, a customer-individual element designation, usage location of a functional element at the customer, or the like. The storage of items of customer information in the memory of a functional element can preferably be initiated by the customer. For example, it can be preferred that a customer does not have authorization to initiate the storage of other items of information except for items of customer information in the memory of a functional element. The items of service information and/or items of customer information can form a part of the items of element information or also separately items of element information can be stored in the memory of the functional element.

A further preferred embodiment of the method is characterized by storing items of element information.

In addition to storing items of process information in the memory of the functional element, it is also preferred to be able also to store items of element information in the memory of the functional element. In this case, for example, existing items of element information can be changed, for example, by overwriting. Items of element information can also be supplemented. This has the advantage that the items of element information can always be kept up-to-date, which can be particularly important, for example, for the process reliability if items of element information change or additional items of information are required for items of element information, for example, to be able to carry out improved checks.

A further preferred embodiment is characterized in that the memory of the first and/or the second and/or a further functional element is a digital nonvolatile memory, in particular, an EEPROM, for example, a One-Wire EEPROM. These preferred memory variants have the advantage of representing a cost-effective, robust, and reliable solution which is energy-efficient at the same time.

Furthermore, it is preferred that the memory of the first and/or the second and/or a further functional element is made fluid-tight, preferably gas-tight, and/or liquid-tight. This embodiment advantageously makes the functional elements particularly suitable for processes in which the functional elements or their memories can be subjected to process media.

In a further preferred embodiment of the method, it is provided that the memory of the first and/or the second and/or a further functional element can be sterilized, preferably can be autoclaved and/or radiation-sterilized, for example, can be beta-sterilized and/or gamma-sterilized. In particular if the functional elements are multiuse elements, the property that the functional elements can be sterilized and/or autoclaved is advantageous.

It is, in particular, preferred here that the memory of the first and/or the second and/or a further functional element has a temperature resistance of at least 100 degrees Celsius, preferably of at least 110 degrees Celsius, preferably of at least 120 degrees Celsius, preferably of at least 130 degrees Celsius, preferably of at least 150 degrees Celsius.

These preferred temperature resistances make the functional elements suitable for a large range of process temperatures, so that the functional elements can be subjected to such temperatures, for example, for sterilizing, or autoclaving.

The preferred features and details described here can each be preferred alone or in any combination with one another as advantageous embodiments.

According to a further aspect of the invention, the object mentioned at the outset is achieved by the use of the above-described method in bioprocess engineering and/or medical technology.

According to a further aspect, the object mentioned at the outset is achieved by a device for use in bioprocess engineering and/or medical technology, comprising a first functional element, which has a memory in which items of element information are stored and the items of element information comprise items of information about the type and the function of the first functional element, a second functional element, and a control unit, wherein the control unit is designed to read the items of element information out of the first functional element and to carry out a check of the read-out items of element information of the first functional element using items of element information which are read out from the second functional element and/or using items of information which are stored in the control unit, wherein the control unit is designed to control at least one of the first and the second functional element in dependence on the check and/or in dependence on the items of element information, and wherein the control unit is designed to store items of process information in the memory of the first functional element.

According to a further aspect, the object mentioned at the outset is achieved by the use of an above-described device in bioprocess engineering and/or medical technology.

According to a further aspect, the object mentioned at the outset is achieved by a functional element for an above-described device for use in bioprocess engineering and/or medical technology and/or for an above-described method, wherein the functional element has a memory in which items of element information are stored and the items of element information comprise items of information about the type and the function of the first functional element, wherein the functional element is designed to be controlled by a control unit, and wherein the memory is designed to be read out by the control unit and/or an evaluation unit, and wherein the memory is designed so that items of process information are storable in the memory by the control unit and/or an evaluation unit.

The method described here and its possible refinements preferably have features or method steps which, in particular, make it suitable to be used with a device described here and/or a functional element described here and the respective possible refinements. Furthermore, the device described here and/or the functional element described here and the respective possible refinements preferably have features which, in particular, make them suitable to be used with a method described here and its possible refinements.

Reference is also made to the preceding description of the corresponding method features with respect to the advantages, embodiment variants, and embodiment details of these further aspects and their respective possible refinements.

The above-described device and the above-described method and the above-described functional element are suitable, in particular, for use in bioprocess engineering and/or medical technology.

### BRIEF DESCRIPTION OF THE DRAWINGS

Preferred exemplary embodiments are described by way of example on the basis of the appended Figures. In the Figures:

FIG. 1 shows a schematic illustration of a flow chart of an example of a method for controlling functional elements in bioprocess engineering and/or medical technology;

FIG. 2 shows a schematic illustration of an example of a device for use in bioprocess engineering and/or medical technology;

FIG. 3 shows a schematic illustration of an example of items of element information and items of process information in the memory of a functional element; and

FIG. 4 shows a schematic illustration of an example of items of information stored in a control unit.

### DETAILED DESCRIPTION OF THE EMBODIMENTS

In the Figures, identical or essentially functionally identical elements are provided with the same reference signs. General descriptions generally refer to all embodiments if differences are not explicitly indicated.

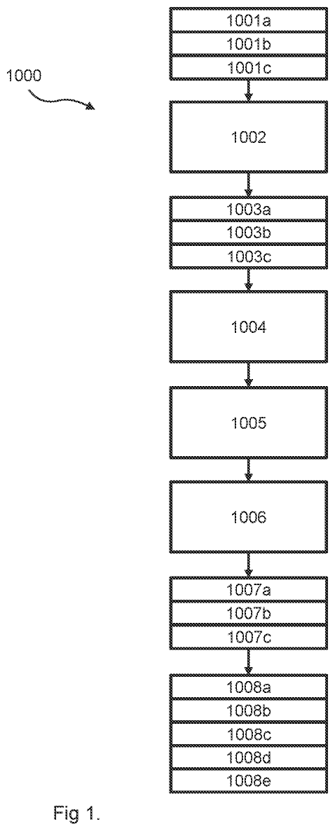

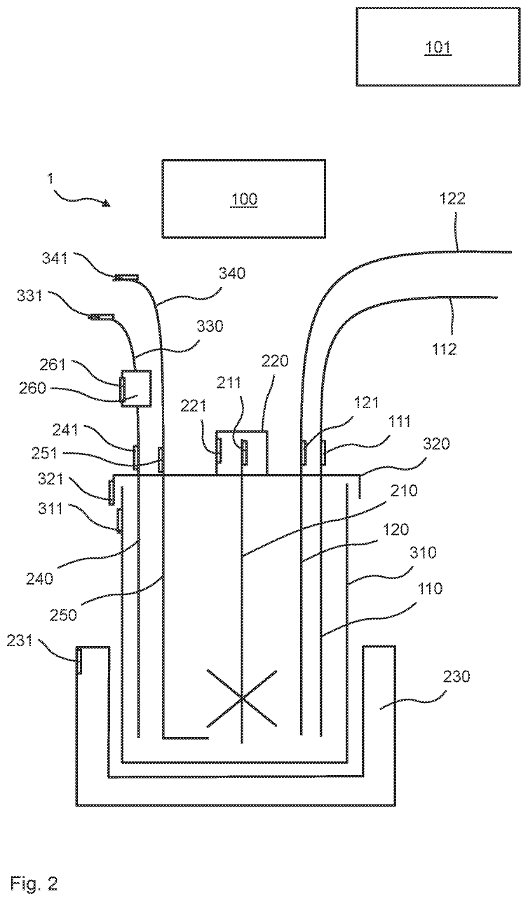

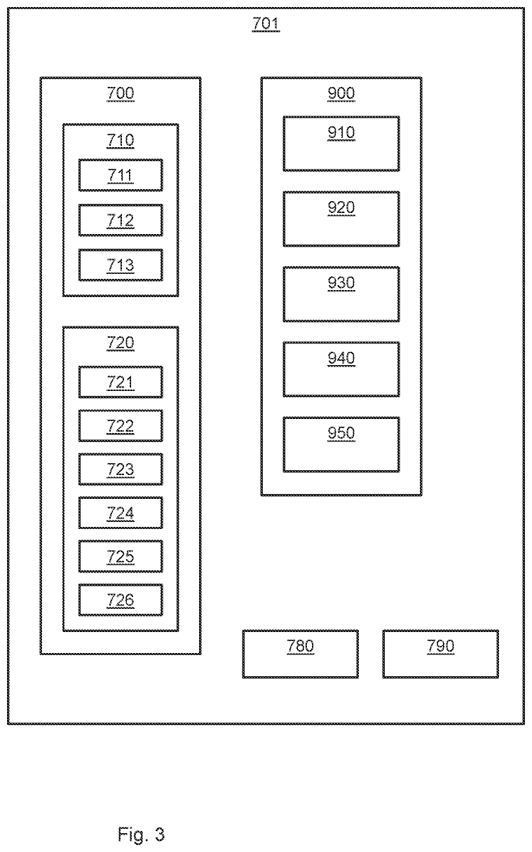

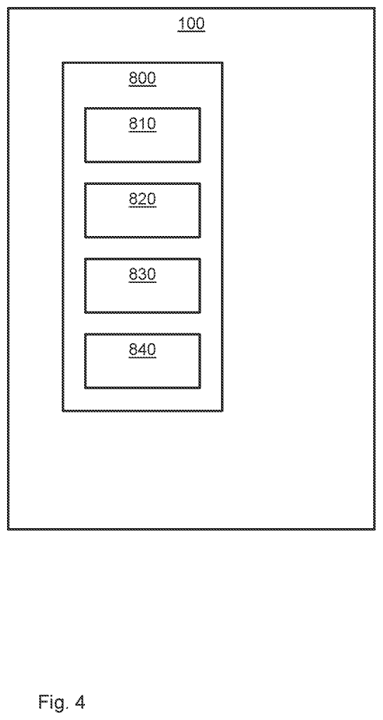

FIG. 1 shows a schematic illustration of a flow chart of an example of a method 1000 for controlling functional elements 110, 120, 210, 220, 230, 240, 250, 260, 310, 320, 330, 340 in bioprocess engineering and/or medical technology. FIG. 2 schematically shows an example of a device for use in bioprocess engineering or medical technology, in the form of the bioreactor 1 here. FIGS. 3 and 4 show examples of items of element information 700 and items of process information 900 in the memory 701 of a functional element (FIG. 3) and an example of items of information 800 stored in a control unit 100 (FIG. 4).

The method 1000 and its steps are explained hereinafter on the basis of the example shown in FIG. 2 of a device for use in bioprocess engineering and/or medical technology, in the form of a bioreactor 1 here. The method and the device are not restricted to the examples and combinations of features shown here, however.

The bioreactor 1 shown by way of example in FIG. 2 is connected to a control unit 100 and to an evaluation unit 101. The connection between the bioreactor 1 and the evaluation unit 101 can take place directly or indirectly via the control unit 100, and furthermore the connection between the bioreactor 1 and control unit 100 and the evaluation unit 101 can take place in a wired or wireless manner.

The bioreactor 1 has multiple functional elements, specifically sensors, actuators, and apparatus components.

As apparatus components, the bioreactor 1 has a bioreactor vessel 310 and a head plate 320 and an exhaust hose 330 and a gassing hose 340.

As actuators, the bioreactor 1 has a stirrer 210 and a stirring drive 220 and furthermore a temperature control unit 230 and a heating sleeve 260 for the exhaust hose 330. Further actuators are a gassing probe 250 and a degassing pipe 240.

The bioreactor 1 moreover has a temperature sensor 110 and a pH sensor 120, which can be connected via lines 112, 122 to further components, for example, to the control unit 100 and/or the evaluation unit 101.

The exhaust hose 330 and/or the gassing hose 340 can preferably also be connected to media reservoirs (not shown here) or further components. The stirring drive 220 is preferably connected to an energy source (not shown).

In the example shown in FIG. 2, all functional elements 110, 120, 210, 220, 230, 240, 250, 260, 310, 320, 330, 340 each have a memory, which is illustrated in more detail hereinafter. However, embodiments are also possible in which only one functional element, two functional elements, or multiple functional elements each have a memory.

For example, the stirrer 210 has a memory 211, the stirring drive 220 has a memory 221. The bioreactor vessel 310 has a memory 311 and the head plate 320 has a memory 321. The temperature control unit 230 has a memory 231. The boundary probe 250 has a memory 251 and the gassing hose 340 connected to the gassing probe 250 has a memory 341. The degassing pipe 240 has a memory 241 and the exhaust hose 330 connected to the degassing pipe 240 has a memory 331. The heating sleeve 260 for the exhaust hose 230 has a memory 261. The two sensors 110, 120 each have a memory 111, 121. Each of the memories 111, 121, 211, 221, 231, 241, 251, 261, 311, 321, 331, 341 of the functional elements 110, 120, 210, 220, 230, 240, 250, 260, 310, 320, 330, 340 can be constructed like the memory 701 shown in FIG. 3 or similarly.

In the example shown in FIG. 1 of the method 1000 for controlling functional elements 110, 120, 210, 220, 230, 240, 250, 260, 310, 320, 330, 340 in bioprocess engineering and/or medical technology, in step 1001a, firstly a first functional element, here in the form of the bioreactor vessel 310, for example, is provided and in step 1001b a second functional element, here, for example, in the form of the stirrer 210, is provided and in step 1001c, the further fraction elements, for example, in the form of the further functional elements 110, 120, 220, 230, 240, 250, 260, 320, 330, 340 mentioned by way of example with reference to FIG. 2, are provided.

In step 1002, the functional elements 110, 120, 210, 220, 230, 240, 250, 260, 310, 320, 330, 340 are connected to the control unit 1000, preferably in a wired or wireless manner.

In step 1003a, items of element information 700 are read out from the memory 311 of the first functional element in the form of the bioreactor vessel 310. In step 1003b, items of element information are read out from the memory 211 of the second functional element in the form of the stirrer 210. In step 1003c, the further items of element information are read out from the memories 111, 121, 221, 231, 241, 251, 261, 321, 331, 341 of the further functional elements 110, 120, 220, 230, 240, 250, 260, 320, 330, 340.

In step 1004, a check is carried out of the read-out items of element information 700 from the various functional elements 110, 120, 210, 220, 230, 240, 250, 260, 310, 320, 330, 340 or the memories 111, 121, 211, 221, 231, 241, 251, 261, 311, 321, 331, 341 thereof and/or using items of information 800 which are stored in the control unit 100.

In step 1005 one or more of the functional elements 110, 120, 210, 220, 230, 240, 250, 260, 310, 320, 330, 340 and/or a process to be carried out are preferably configured in dependence on the check carried out in step 1004.

In step 1006, the functional elements 110, 120, 210, 220, 230, 240, 250, 260, 310, 320, 330, 340 are then controlled, in particular, by means of the control unit 100, in dependence on the check carried out in step 1004 and/or in dependence on the elementary functions 700.

In steps 1007a, 1007b, 1007c, items of process information 900 are then stored in the memory 111, 121, 211, 221, 231, 241, 251, 261, 311, 321, 331, 341 of the functional elements 110, 120, 210, 220, 230, 240, 250, 260, 310, 320, 330, 340.

In step 1008a, items of process information 900 are then preferably also stored in the memory of the control unit 100 and/or in step 1008b, items of process information 900 are stored in a memory of the evaluation unit 101.

In step 1008c, items of service information 780 and/or items of customer information 790 are preferably stored in the memory 111, 121, 211, 221, 231, 241, 251, 261, 311, 321, 331, 341 of one or more functional elements 110, 120, 210, 220, 230, 240, 250, 260, 310, 320, 330, 340.

The memory 701, shown, by way of example, in FIG. 3, contains items of element information 700, items of process information 900, items of service information 780, and items of customer information 790. Preferably, one, two, multiple, or all of the memories 111, 121, 211, 221, 231, 241, 251, 261, 311, 321, 331, 341 of the functional elements 110, 120, 210, 220, 230, 240, 250, 260, 310, 320, 330, 340 can be designed like the memory 701 shown, by way of example, in FIG. 3.

The items of element information 700 preferably comprise specifications 710 about the type of the functional element and/or specifications 720 about option of the functional element. The specifications 710 about the type of the functional element can comprise, for example, a serial number 711, an article number 712, or a type specification 713. The specifications 720 about the function of the functional element can comprise, for example, specifications 721 about the operating parameters, specifications 722 about compatibilities, specifications 723 about the usability of the respective functional element in various processes, specifications 724 about the calibration of the respective functional element, specifications 721 about the CE identification of considered functional element, specifications 700 sixth 20 about service intervals to be maintained and/or maximum operating duration of the functional element.

The items of process information 900 can preferably include specifications 910 about a process carried out, specifications 920 of process parameters used in a process, specifications 930 of the operating parameters using which functional element was operated in a process, and/or specifications 940 about further functional elements used together with the functional element and/or specifications 950 about process results and/or process errors.

Furthermore, items of service information 780 and/or items of customer information 790 can be stored in the memory 701.

The items of information 800 stored in a memory of the control unit 100 can comprise, for example, specifications 810 about compatibilities of functional elements, specifications 820 about the usability of functional elements in various processes, specifications 830 about processes to be carried out, and/or specifications 840 of the process parameters to be used in a process.

Preferably, the items of element information 700, the items of process information 900, the items of service information 780, and/or the items of information 790 below in a memory 701 of a functional element can each only be supplemented and/or changed by an authority authorized for this purpose. For example, the authorization for supplementing and/or changing items of service information 780 can be restricted to service personnel authorized for this purpose. Items of customer information 790, in contrast, can also be changed or supplemented by customers, for example. Items of element information 700, for example, can preferably only be supplemented and/or changed by the manufacturer or by authorities authorized by him or her.

Using the solution described here, it is possible advantageously and efficiently, among other things, to increase the process reliability and facilitate maintaining quality guidelines such as GMP and to create documentation required for this purpose more easily.

1.-15. (canceled)

16. A method for controlling functional elements in bioprocess engineering or medical technology, comprising the steps of:
providing a first functional element, which has a memory in which items of element information are stored and the items of element information comprise specifications about the type and the function of the first functional element;
providing a second functional element;
connecting the first and the second functional element to a control unit;
reading the items of element information out of the first functional element;
carrying out a check of the read-out items of element information of the first functional element using items of element information which are read out from the second functional element and/or using items of information which are stored in the control unit;
controlling at least one of the first and the second functional element in dependence on the check and/or in dependence on the items of element information; and
storing items of process information in the memory of the first functional element.

17. The method as claimed in claim 16, wherein the first and/or the second functional element is selected from a group comprising:
a sensor;
an actuator; or
an apparatus component.

18. The method as claimed in claim 16, wherein the second functional element has a memory in which items of element information are stored and the items of element information comprise specifications about the type and the function of the second functional element.

19. The method as claimed in claim 16, further comprising the steps of:
providing one or more further functional elements, wherein one or more or all of the further functional elements each has a memory in which items of element information are stored and the items of element information comprise specifications about the type and the function of the respective functional element;
reading the items of element information out of the second functional element; and
reading the items of element information out of one, multiple, or all of the further functional elements.

20. The method as claimed in claim 19, wherein when carrying out the check, the read-out items of element information of the second, one, multiple, or all further functional elements are taken into consideration.

21. The method as claimed in claim 16, wherein the specifications about the type of the first functional element comprise whether the respective functional element is designed as a sensor, actuator, or apparatus component; or
wherein the specifications about the type of the first functional element comprise a serial number of the respective functional element, comprise an article number of the respective functional element, comprise a type specification of the respective functional element, or comprise specifications about the manufacturing of the respective functional element.

22. The method as claimed in claim 16, wherein the specifications about the function of the first functional element further comprises:
specifications about operating parameters of the respective functional element;
specifications about compatibilities of the respective functional element with other functional elements;
specifications about the usability of the respective functional element in various processes;
specifications about the calibration of the respective functional element;
specifications about the CE identification of the respective functional element; or
specifications about the service intervals to be observed and/or the maximum operating duration of the respective functional element.

23. The method as claimed in claim 16, wherein the items of information which are stored in the control unit comprise:
specifications about compatibilities of functional elements;
specifications about the usability of functional elements in various processes;
specifications about processes to be carried out, such as type and/or duration of the respective process; or
specifications of the process parameters to be used in a process.

24. The method as claimed in claim 16, wherein the items of process information further comprise:
specifications about a process which was carried out, such as type and/or duration of the process;
specifications of the process parameters used in a process;
specifications of the operating parameters, using which the respective functional element and/or further functional elements were operated in a process;
specifications about further functional elements used together with the respective functional element, in particular the items of element information thereof or parts thereof; or
specifications about process results and/or process errors.

25. The method as claimed in claim 19, wherein carrying out the check further comprises the steps of:
comparing the compatibilities of functional elements with respect to the joint use thereof, the usability thereof in a planned process, or the usability thereof in a planned process environment;
configuring the first, the second, one, or multiple of the further functional elements or a process to be carried out in dependence on the check;
storing items of process information in the memory of the control unit;
storing items of process information in a memory of an evaluation unit;
storing items of service information in the memory of the first and/or the second and/or a further functional element;
storing items of customer information in the memory of the first and/or the second and/or a further functional element; or
storing items of element information.

26. The method as claimed in claim 16, wherein the memory of the first, the second, or a further functional element is a digital nonvolatile memory, in particular an EEPROM;
wherein the memory of the first, the second, or the further functional element is made fluid-tight;
wherein the memory of the first, the second, or the further functional element can be sterilized by autoclaved or radiation-sterilized, including beta-sterilized and/or gamma-sterilized; or
wherein the memory of the first, the second, and/or the further functional element has a temperature resistance of at least 100 degrees Celsius

27. The method as claimed in claim 26, wherein the memory of the first, the second, and/or the further functional element has a temperature resistance of at least 110 degrees Celsius,

28. The method as claimed in claim 27, wherein the memory of the first, the second, and/or the further functional element has a temperature resistance of at least 120 degrees Celsius.

29. The method as claimed in claim 28, wherein the memory of the first, the second, and/or the further functional element has a temperature resistance of at least 130 degrees Celsius.

30. The method as claimed in claim 29, wherein the memory of the first, the second, and/or the further functional element has a temperature resistance of at least 150 degrees Celsius.

31. The use of the method as claimed in claim 16 in bioprocess engineering or medical technology.

32. A device for use in bioprocess engineering or medical technology, comprising:
a first functional element, which has a memory in which items of element information are stored and the items of element information comprise items of information about the type and the function of the first functional element;
a second functional element; and
a control unit;
wherein the control unit is designed to read the items of element information out of the first functional element and to carry out a check of the read-out items of element information of the first functional element using items of element information which are read out from the second functional element and/or using items of information which are stored in the control unit;
wherein the control unit is designed to control at least one of the first and the second functional element in dependence on the check and/or in dependence on the items of element information; and
wherein the control unit is designed to store items of process information in the memory of the first functional element.

33. The use of a device as claimed in claim 32 in bioprocess engineering or medical technology.

34. The method as claimed in claim 16, wherein the functional element has a memory in which items of element information are stored and the items of element information comprise items of information about the type and the function of the first functional element, wherein the functional element is designed to be controlled by the control unit, and wherein the memory is designed to be read out by the control unit or an evaluation unit, and wherein the memory is designed so that items of process information are storable in the memory by the control unit or an evaluation unit.

35. A functional element for a device for use in bioprocess engineering or medical technology as claimed in claim 32, wherein the functional element has a memory in which items of element information are stored and the items of element information comprise items of information about the type and the function of the first functional element, wherein the functional element is designed to be controlled by the control unit, and wherein the memory is designed to be read out by the control unit or an evaluation unit, and wherein the memory is designed so that items of process information are storable in the memory by the control unit or an evaluation unit.
